(19) United States
(12) Patent Application Publication
(10) Pub. No.: US 2010/0127705 A1
(43) Pub. Date: May 27, 2010

(54) METHOD AND APPARATUS FOR MAGNETIC INDUCTION TOMOGRAPHY

(75) Inventor: Hermann Scharfetter, Graz (AT)

Correspondence Address: RATNERPRESTIA, P.O. BOX 980, VALLEY FORGE, PA, 19482, US

(73) Assignees: Technische Universitat Graz, Graz (AT); Forschungsholding TU Graz GmbH, Graz (AT)

(21) Appl. No.: 12/374,838

(22) PCT Filed: Jul. 24, 2007
(86) PCT No.: PCT/AT2007/000359

§ 371 Date: Nov. 12, 2009

(30) Foreign Application Priority Data
Jul. 24, 2006 (AT) A 1255/2006

(51) Int. Cl. G01R 33/48; G01R 33/44

(52) U.S. Cl. 324/310; 324/318

(57) ABSTRACT

A method and an apparatus for magnetic induction tomography, in which an object with inhomogeneous passive electrical properties is exposed to an alternating magnetic field by excitation coils located at different positions, from which receiver coils located at different positions pick up AC signals which contain information concerning the electrical conductivity and its distribution in the object, and images of the spatial electrical properties in the interior of the object are reconstructed from the amplitudes and phases of the received signals, whereas the measurement is carried out at least 2 frequencies and an additional perturbation of the coils and/or the field geometry so as to determine a correction factor with which it is possible to widely eliminate spurious signals generated by changes of the geometry during the object measurement.

The invention relates to an apparatus for magnetic induction tomography and a method herefor, in which an object having inhomogeneous passive electrical properties is exposed to alternating magnetic fields by means of coils located at different excitation positions, AC voltage signals which contain information about the electrical conductivity and its distribution in the object, are picked up with receiver coils located at different receiving positions and an image of the spatial distribution of the electrical properties in the object is reconstructed from the received signals with the aid of their different phases and amplitudes.

In medical diagnostics, as previously, there is a need for methods of investigation which operate rapidly, cheaply and without exposing the patient to ionising radiation, in particular for mammography methods for the early detection of breast cancer.

Methods have become known under the designation “electrical impedance tomography” which appear very attractive in regard to dispensing with x-ray radiation. The starting point for this method is the demonstrated significant contrast of the electrical conductivity between tumour tissue and healthy tissue and this has become known as a commercial quasi-imaging system (http:imaginis.com/t-scan/how-work.asp) which is based on a multi-channel impedance measurement.

The present problems of this method lie, on the one hand, in the relatively low spatial resolution and in the fact that electrodes must be in contact with the surface of the body.

The problem of low resolution can be put into perspective if the evaluation method yields such a good contrast that it is possible to at least detect a lesion. In this regard, the application of spectral methods, i.e. multi-frequency evaluation is very promising. As before, the use of electrodes remains a problem which is poorly defined because of the electrode-skin transition with its electrochemical potentials, and introduces considerable artefacts into the measurement result which are difficult to eliminate, or can only be eliminated with a high expenditure of time (repeated measurements), so that a desired advantage is again lacking.

For these reasons, attempts are being made to go over to electrodeless measurement methods which, however, also have an evaluation of the electrical conductivity distribution as their starting basis. Such methods are the starting point of the present invention and are designated as “magnetic induction tomography”. [Literature on this: Griffiths H., Magnetic induction tomography. Meas. Sci. Technol. 26: 1126-1131. Korzhenevskii A. V., and V. A. Cherepenin. Magnetic induction tomography. J. Commun. Tech. Electron. 42; 469-474, 1997].

A basic presentation on the multi-frequency modification of magnetic induction tomography, i.e. magnetic induction spectroscopy, can be found in Hermann Scharfetter, Roberto Casanas and Javier Rosell, “Biological Tissue Characterization by Magnetic Induction Spectroscopy (MIS): Requirements and Limitations”, IEEE Trans. Biomed. Eng. 50, 870-880, 2003.

One object of the invention is to provide an apparatus and a method for electrodeless impedance spectroscopy in which the hitherto unavoidable strong instability of the measurement signals is noticeably reduced so that simple and rapid measurements are possible which are particularly suitable for the early detection or screening of breast tumours. [Literature on this: Scharfetter H. Systematic errors in frequency-differential imaging with magnetic induction tomography (MIT). Proceedings of the 6^{th} Conference on Biomedical Applications of Electrical Impedance Tomography, London, Jun. 22-24, 2005]

This object is achieved by a method according to the preamble of claim 7 in which according to the invention, a measurement is carried out at least two different frequencies and an additional perturbation of the coils and/or the field geometry so as to determine a correction factor with which spurious signals generated by changes of the geometry and amplifier drift during the object measurement can be substantially eliminated.

At this point, it should be noted that within the scope of this document the term “changes of the geometry” should be understood not only, for example as a temperature-induced change in the coil geometry but this term should also include other perturbations which are caused, for example, by metal objects present or moving outside the actual measurement range.

In this context, it can be advantageous if the perturbation is introduced by an alternating movement of the coils relative to each other or if the perturbation is introduced by the movement of a conductive sample in the sensitive region of the coils. In this way, the magnitude and type, e.g. frequency of the perturbation can be influenced so that an approximation to perturbations occurring during the measurement is possible.

However, it can also be advantageous if the perturbation is introduced by not previously defined, statistical movements of the coils since the expenditure on apparatus for introducing the perturbation is hereby minimised.

In practice, it is expedient if the object is exposed to the alternating magnetic fields of several excitation coils which are stationary with respect to the object and that signals are received and processed from several receiver coils which are stationary with respect to the object. However, such a configuration is not essential since in principle, a coil, either a receiver or excitation coil, can be rotatable, for example, about the investigated object and can then be temporarily stopped at predetermined positions during the measurement.

In a recommended variant with a view to an increase in speed, comprising a plurality of simultaneously activated exciter coils, it is provided that the excitation frequencies are split up into several closely spaced sub-frequencies, wherein the closely neighbouring sub-frequencies deviate from each other only insignificantly with respect to the frequency dependence of the passive electrical properties of the target tissue. In this case, it has proven to be practical if the neighbouring sub-frequencies differ from one another by less than 10%.

A favourable variant in the sense of a defined allocation of the frequencies and coils is that in which the number of excitation coils corresponds to the number of sub-frequencies per excitation frequency and each first, second, third etc. excitation coil is fed with the first, second, third etc. sub-frequency of the excitation frequency.

The object is also achieved with an apparatus, comprising at least one excitation coil for the introduction of an alternating magnetic field into the target body with an inhomogeneous conductivity distribution at several excitation positions and at least one receiver coil for the pickup of received signals at several different receiving positions, with a means for the processing of the received signals which reconstructs an image of the spatial electrical properties in the object from the received signals with the aid of their different phases and amplitudes, in which according to the invention the means for the processing of the received signals is capable of determining a correction factor by a measurement at least two different frequencies and introducing a perturbation of the coils and/or field geometry with the aid whereof the spurious signals generated by changes of the geometry during the object measurement can be substantially eliminated.

It is also favourable here if the apparatus comprises a plurality of excitation coils and a plurality of receiver coils, wherein excitation and receiver coils are stationary with respect to the object.

Furthermore, for the intentional introduction of perturbations it is expedient if the excitation and/or receiver coils are movable in at least one degree of freedom so that a movement can be introduced in at least one of the coils. At the same time, it is frequently advisable if an actuator is provided for introducing a movement in at least one of the coils.

In an expedient embodiment it can be provided that a movable conductive perturbation object is provided in the sensitive region of the coils.

In order to eliminate a priori the influence of external interference fields as far as possible, it is appropriate if the receiving coils are configured as gradiometer coils.

The invention together with further advantages is explained in detail hereinafter with reference to exemplary embodiments which are explained in detail in connection with the appended drawings. In the figures

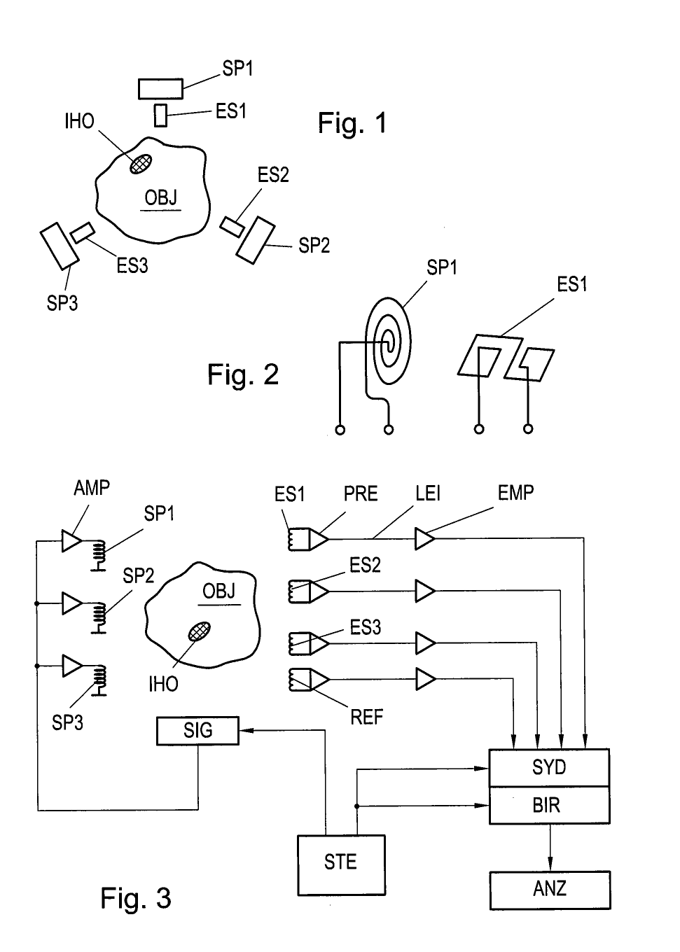

FIG. 1 shows schematically the fundamental arrangement of excitation and receiving coils around an object in which an inhomogeneity is to be detected,

FIG. 2 shows illustratively and schematically an excitation coil and a receiving coil configured as a gradiometer coil,

FIG. 3 shows in a block diagram the principle of a measurement arrangement according to the invention,

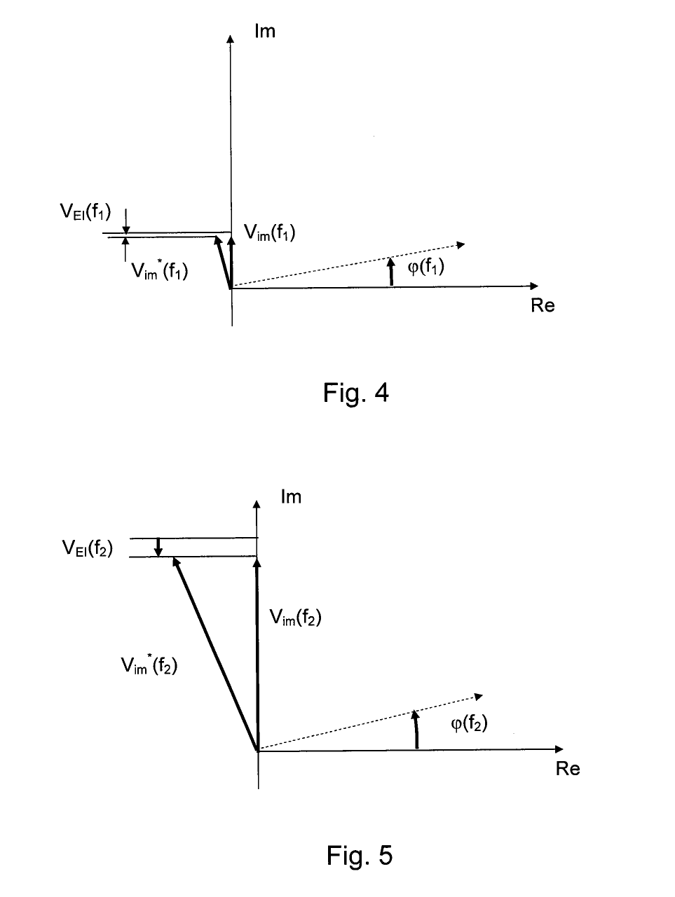

FIGS. 4 to 7 show, in vector diagrams, the occurrence or introduction of significant error values,

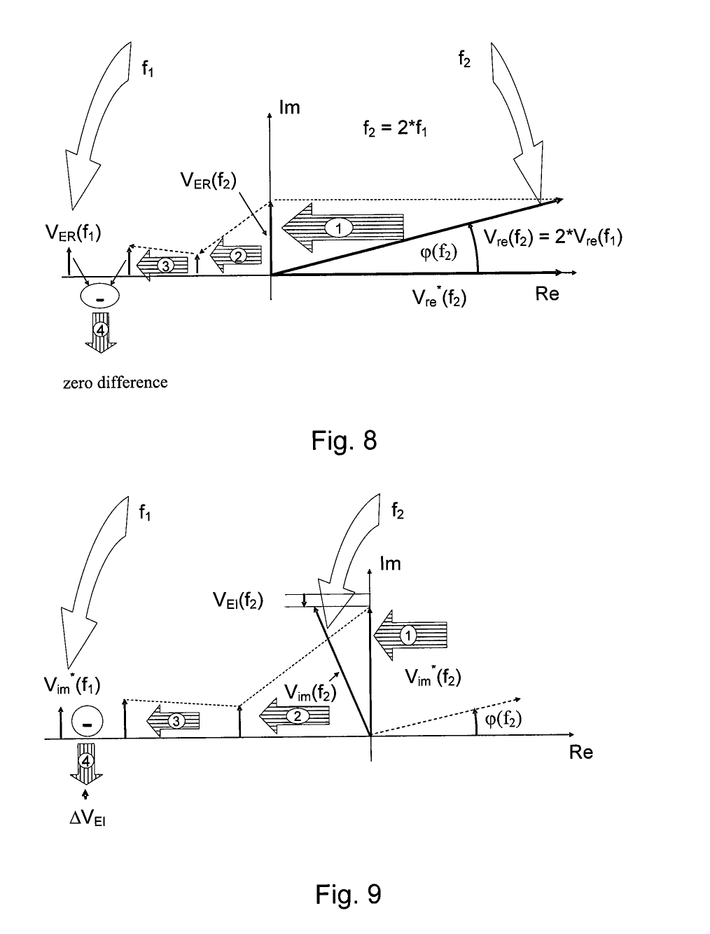

FIGS. 8 and 9 show the method according to the invention for eliminating errors with reference to diagrams and

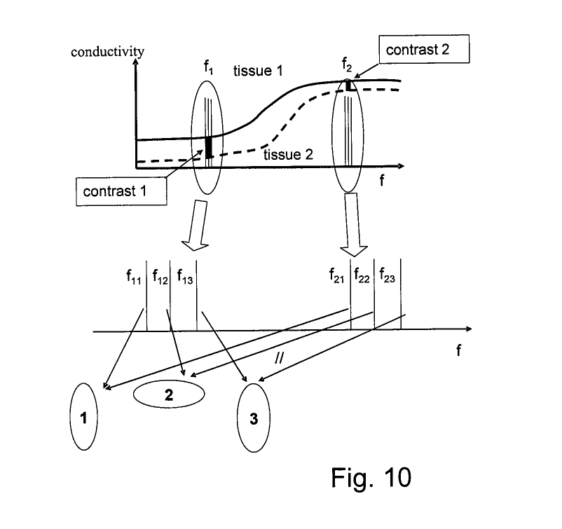

FIG. 10 shows a variant of the invention with split excitation frequencies with reference to a diagram.

Reference is initially made to FIGS. 1 to 3.

FIG. 1 shows schematically an object OBJ to be investigated, having an inhomogeneity IHO which has a conductivity different from the remainder of the object, for example, a lesion inside a part of the body such as the brain or a female breast.

Excitation coils SP1, SP2 and SP3 are arranged at various positions outside the object to be investigated, but as close as possible thereto, in the present case three excitation coils are used, but the number of excitation coils can naturally also be substantially higher according to the desired resolution and the type of object. As shown in FIG. 3, these excitation coils are supplied with AC current, originating from a signal generator SIG, having amplifiers AMP connected ahead thereof for each excitation coil. Also shown in FIG. 1 are three receiver coils ES1, ES2, ES3 which are located in the area of the excitation coils here but can also be arranged at completely different positions. According to FIG. 3, a pre-amplifier PRE is provided for each of the receiver coils and these pre-amplifiers are connected via shielded lines LE1 to further amplifiers EMP whose outputs are supplied to a synchronous detector SYD. The synchronous detector SYD receives the necessary synchronous signal from the sine generator SIG. An image reconstruction BIR also takes place in the unit with the synchronous detector and its output signal can then be passed to a display ANZ such as a screen, a printer etc. The synchronous detector SYD, the amplifiers AMP and the image reconstruction BIR are controlled by a control unit STE. A coil designated as REF is used to obtain a reference signal.

Since the signals to be evaluated which are picked up by the receiver coils are in fact many orders of magnitude smaller than the excitation signals of the excitation coils, care is initially taken to ensure that the fields of the excitation coils do not act directly on the receiver coils. For this purpose, the receiver coils according to FIG. 2 are configured as so-called gradiometer coils which can additionally be arranged orthogonally in relation to the excitation coils. Such gradiometer coils are in principle insensitive to other fields as long as these fields are homogeneous since the same voltage but with opposite sign is induced in each coil half. Since neither the receiver coil geometry is perfect nor are the interference fields which occur actually homogeneous, appreciable spurious signals occur however, partly from long- to short-wavelength transmitters. The processing by a synchronous detector in a known manner can considerably reduce the perturbation level here.

The signals received in the receiver coils ES1, ES2 and ES3 depend, inter alia, on the distribution of the electrical conductivity inside the object OBJ to be investigated and it has been shown that tissue variations in the breast tissue, for example, lead to conductivity variations which are sufficiently large to allow a mammographic representation following evaluation in a microprocessor of the image processing DVA. Details need not be discussed here since these can be found, for example, in the citation already mentioned.

It has already been mentioned that the fraction of actual signals of interest at the output of the receiver coils is extremely small, more precisely extending down into the nanovolt range so that it is also understandable that even small changes in the field geometry can lead to considerable errors. Usual error sources in this case are the mutual position of the various coils which can unfavourably influence the measurement as a result of slight temperature variations. Changes in the coil geometry due to vibrations or quite generally mechanical loads should also be mentioned here. The same applies to perturbations of the field by metallic objects moving outside the actual range of investigation. It is sufficient if persons with metallic objects in their pocket walk past the patient and naturally other perturbations, for example, caused by passing vehicles etc. are also possible. The subject matter of the present invention is the correction of such errors and an error correction algorithm used in the invention will be explained in detail hereinafter.

A frequency-differential imaging of the conductivity is based on the scaled difference formula:

$$Δ {V}_{im} ( {f}_{1} , {f}_{2} ) = Im \{ V ( {f}_{1} ) - {( \frac{{f}_{1}}{{f}_{2}} )}^{2} V ( {f}_{2} ) \} \qquad ( 1 )$$

Here ΔVᵢₘ is the data set incorporated in the image reconstruction algorithm and V(f₁), V(f₂) are the voltages at two different frequencies f₁ and f₂. The reason why only the imaginary part is used in described elsewhere. [Brunner P, Merwa R, Missner A, Rosell J, Hollaus H, Scharfetter H. Reconstruction of the shape of conductivity spectra using differential multi-frequency magnetic induction tomography, Physiol Meas 27, p 233-p 248, 2006]

Equation (1) was proposed in the publication ‘Brunner P, Merwa R, Missner A, Rosell J, Hollaus H, Scharfetter H. Reconstruction of the shape of conductivity spectra using differential multi-frequency magnetic induction tomography, Physiol Meas 27, p 233-p 248, 2006’.

### Error Values

Each phase shift φ between the reference voltage and the measured voltage leads to two types of errors in the imaginary part of the signals in (V(f)):

Error V_{EI} is the difference between the actual imaginary part Vᵢₘ and its projection Vᵢₘ* on the imaginary axis (FIG. 4). This error is proportional to sin(φ). For small angles this error is generally small but the angle φ and therefore the error becomes larger with increasing frequencies, as is shown in FIG. 5 for the frequency f₂. In this example f₂=2f₁ so that as a consequence of the quadratic frequency dependence of the sensitivity in relation to the conductivity Vᵢₘ is four times larger at the higher frequency than at the lower frequency.

For the following investigation it is assumed that as a result of its small projection angle φ, V_{EI} is negligible (<10% of Vᵢₘ).

Error V_{ER} is the projection of the—generally relatively large—real part on the imaginary axis. This error can be very large and on account of the thermally induced changes in the electrical and geometrical parameters of the coil system, depends on the temperature. Vᵣₑ consists partly of a “true” signal as a result of the imaginary part of the conductivity of the target object but this part is generally substantially smaller than the imaginary part. Components caused by an inaccurate setting of gradiometer coils, by vibration shift (V_{vibr}) and by objects having high conductivity, e.g. metal objects in the vicinity of the coils (V_{hicond}) are more important.

The following conditions are assumed hereinafter:

(a) Equation 1 is used for a scaled frequency-differential imaging of the conductivity.
(b) As a result of small phase angles φ, V_{EI} is negligible.
(c) V_{ER} is considered to be an essential error to be eliminated before an image reconstruction.

### Correction of V_{ER}

The frequency dependence of V_{ER} is given by:

V_{ER}(f₁)=Vᵣₑ(f₁)sin(φ(f₁))

V_{ER}(f₂)=Vᵣₑ(f₂)sin(φ)(f₂))

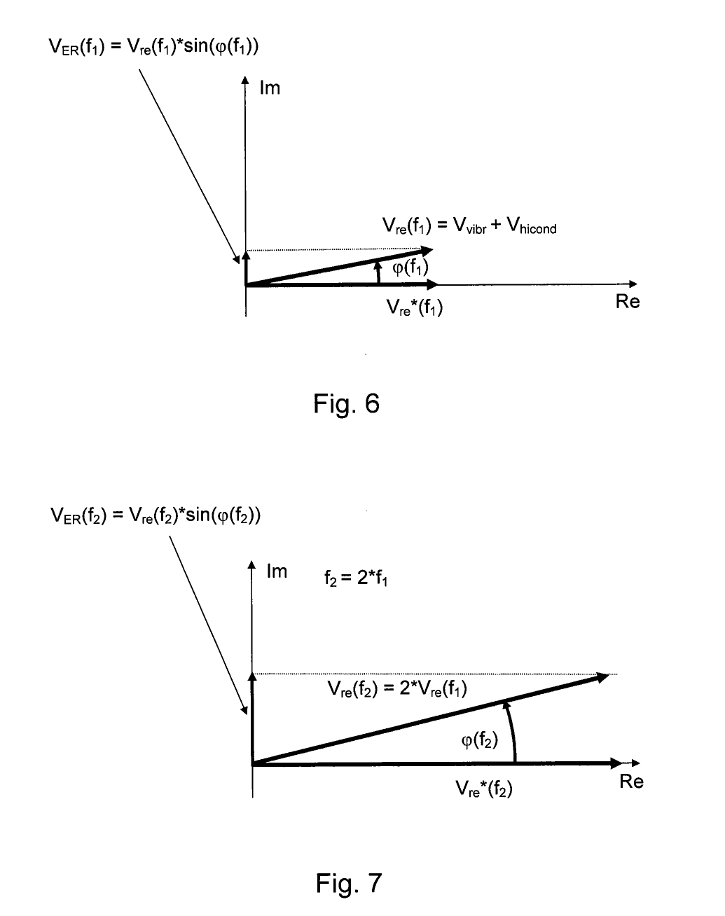

FIGS. 6 and 7 show these components graphically for the case f₂=2f₁.

Both components V_{vibr} and V_{hicond} of the signal Vᵣₑ are proportional to the excitation frequency and V_{ER}(f₂) can thus be expressed as follows as a function of V_{ER}(f₁):

$${V}_{ER} ( {f}_{2} ) = {V}_{re} ( {f}_{1} ) \frac{{f}_{2}}{{f}_{1}} sin ( ϕ ( {f}_{2} ) ) = {V}_{ER} \frac{{f}_{2}}{{f}_{1}} \frac{sin ( ϕ ( {f}_{2} ) )}{sin ( ϕ ( {f}_{1} ) )} \qquad 2 )$$

When Equation (1) is applied to the differential imaging, we obtain:

$$Δ {V}_{ER} = {V}_{ER} ( {f}_{1} ) - {( \frac{{f}_{1}}{{f}_{2}} )}^{2} {V}_{ER} ( {f}_{2} ) = {V}_{ER} ( {f}_{1} ) ( 1 - \frac{{f}_{2} sin ( ϕ ( {f}_{2} ) )}{{f}_{1} sin ( ϕ ( {f}_{1} ) )} ) \qquad ( 3 )$$

FIG. 8 shows the complete processing chain wherein the step shown at the top according to Equation (3) is designated as “step 2”.

The expression according to Equation (3) becomes zero if:

$$\frac{{f}_{1}}{{f}_{2}} \frac{sin ( ϕ ( {f}_{2} ) )}{sin ( ϕ ( {f}_{1} ) )} = 1 \qquad ( 4 )$$

In a suitably designed measurement system there is a broad range of frequencies for which this condition is approximately satisfied, i.e.

$$\frac{{f}_{1}}{{f}_{2}} \frac{sin ( ϕ ( {f}_{2} ) )}{sin ( ϕ ( {f}_{1} ) )} = \frac{1}{γ} \qquad ( 5 )$$

where γ is close to 1. Multiplying V_{ER} (f₂) in Equation (3) by γ yields the modified differential

$$Δ {V}_{ER} = {V}_{ER} ( {f}_{1} ) - {( \frac{{f}_{1}}{{f}_{2}} )}^{2} {V}_{ER} ( {f}_{2} ) γ \qquad ( 6 )$$

This vanishes when γ has the optimal value:

$${γ}_{opt} = \frac{{f}_{2}}{{f}_{1}} \frac{sin ( ϕ ( {f}_{1} ) )}{sin ( ϕ ( {f}_{2} ) )} \qquad ( 7 )$$

The re-scaling step according to Equation (6) is designated as “step 3” in FIG. 8 and the subtraction as “step 4”.

FIG. 8 shows the cancellation of V_{ER} in four successive steps:

1. Generating the projections

### 2. Re-scaling

3. Correction with γ

### 4. Subtraction

The conditions according to Equations (6) and (7) bring about a modification of the basic equation (1) as follows:

$$Δ {V}_{im} ( {f}_{1} , {f}_{2} ) = Im \{ V ( {f}_{1} ) - {( \frac{{f}_{1}}{{f}_{2}} )}^{2} V ( {f}_{2} ) γ \} \qquad ( {1}^{′} )$$

### Influence on the Desired Signal Components

The method specified above effectively compensates for all the perturbations described, but on the other hand also influences the desired difference signal ΔVᵢₘ to some extent. Ideally, it should hold that:

$$Δ {V}_{im} = {V}_{im} ( {f}_{1} ) - {( \frac{{f}_{1}}{{f}_{2}} )}^{2} {V}_{im} ( {f}_{2} ) \qquad ( 8 )$$

In fact, the original signals Vᵢₘ cannot be measured but only their projections Vᵢₘ*. Thus, we need to calculate:

$$Δ {V}_{IM} = {V}_{im}^{*} ( {f}_{1} ) - {( \frac{{f}_{1}}{{f}_{2}} )}^{2} {V}_{im}^{*} ( {f}_{2} ) γ \qquad ( 9 )$$

We thus obtain a certain deviation, on the one hand since γ differs from 1 and on the other hand on account of the projection angle. An accurate error analysis has been made but for reasons of space and since it is not important for the invention as such, this is not given here. FIG. 9 shows the projections Vᵢₘ* at the two frequencies. Assuming a constant, i.e., non-frequency-dependent, conductivity, Equation (8) gives no difference signal but on account of the projection error, Equation (9) gives a residual difference signal ΔV_{EI} as follows:

$$Δ {V}_{EI} = {V}_{EI} ( {f}_{1} ) - {( \frac{{f}_{1}}{{f}_{2}} )}^{2} {V}_{EI} ( {f}_{2} ) γ \qquad ( 10 )$$

As already mentioned however, this contribution can be neglected.

The remaining influence of γ alone is illustrated with reference to FIG. 9.

FIG. 9 relates to the error in the useful signal as a result of the multiplication by γ and shows four successive steps:

1. Generating the projections

### 2. Re-scaling

3. Correction with γ
4. Subtraction to obtain a small residual ΔV_{EI}.

V_{EI} designates the usually small error as a result of the projection angle.

γ can be determined experimentally. For this purpose, a signal Vᵣₑ is introduced, e.g. by means of a vibration or a highly conductive piece of metal in the sensitive range of the coil arrangement and then γ is adjusted until ΔVᵢₘ vanishes. The signal can be intentionally introduced or not controlled, e.g. on the basis of random vibrations or movements of highly conductive material.

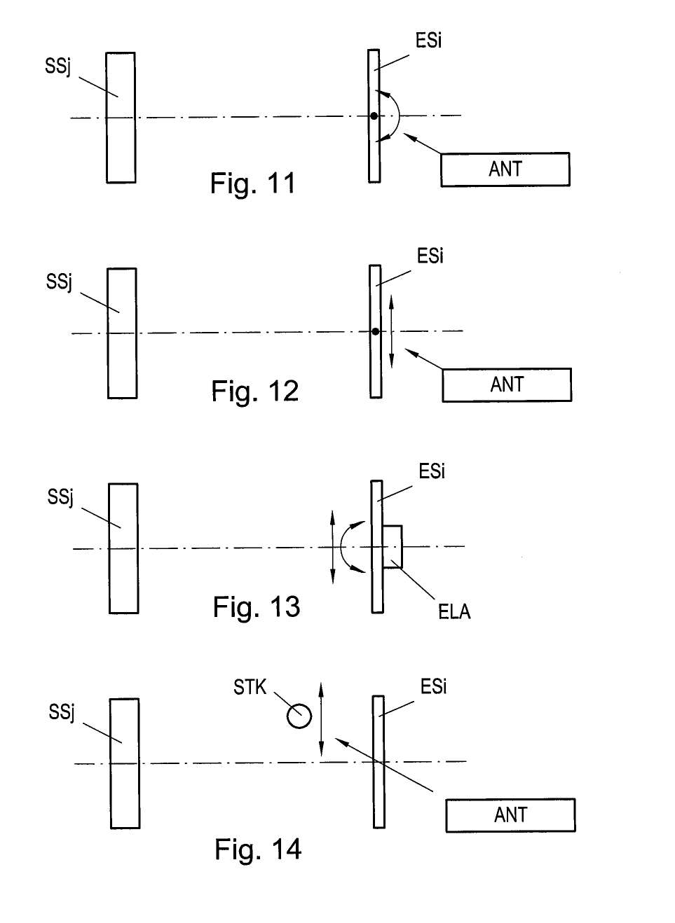

Various possibilities relating to the introduction or the “tolerance” of an introduced perturbation are shown with reference to FIGS. 11 to 14, wherein respectively one excitation coil SSj and one receiver coil ESi are shown. FIG. 11 shows that a receiver coil ESi can be turned about an axis and set in rotary vibration by means of an actuator ANT. For example, a motor with periodic movements can be used for this purpose, it being advantageous if the vibration frequency is known and available since noise-reducing signal processing can take place subsequently in the microprocessor or with the aid of a further synchronous detector.

Another possibility for introducing the desired perturbation (outside the actual measurement) is shown in FIG. 12. Here, the receiver gradiometer coil ESi can be moved translationally, e.g. made to vibrate, for which an actuator ANT is likewise provided. The same as that noted for FIG. 11 applies in principle.

Although a deterministic active introduction of a perturbation is expedient, a stochastic perturbation can also be intentionally allowed, however, in order to carry out the perturbation eliminating process. FIG. 13 shows that the receiver coil ESi is held with the aid of an elastic bearing ELA. Vibrations occurring in the vicinity, e.g. due to steps or the like can have the result that the receiver coil ESi can execute translational and/or rotational movements whereby the perturbation “desired” here is introduced.

The perturbations treated in FIGS. 11 to 13 are based on a change in the coil geometry. As has already been stated further above, the perturbation can also be introduced by a change in the field geometry, in which case a conductive perturbing body STK is driven for this purpose by an actuator ANT, moved in the sense of the parts shown, advantageously periodically, again with a known and available frequency. If the perturbing body STK has sufficient influence as a result of its size or properties, it need not be arranged, as shown, between excitation and receiver coils but can also lie outside. Also, perturbations introduced by a perturbing body SK need not be deterministic but as already mentioned above, they can also be of a stochastic type, due to movements of conductive objects in the area of the coils.

### Phase Correction Network

A further improvement of the invention provides a phase correction network. An important aspect for the applicability in practice is that γ is actually very close to 1 over the entire frequency range. If this condition cannot be adhered to, the system can be optimised by introducing a phase correction network whereby the system is brought to satisfy the condition (5) as accurately as possible. Such a phase correction network can be implemented, for example as a passive PLC network between gradiometer coils and pre-amplifiers or after the pre-amplifiers.

### Multi-Sine Multiple-Carrier Excitation for Spectroscopic “Single-Shot” Multi-Sine Imaging

A rapid and precise imaging is substantially promoted by the simultaneous excitation of many, if not all the coils. For the case of multi-frequency imaging, all the frequencies should be used simultaneously to avoid any drift between the measurements at different frequencies. However, if several coils are excited simultaneously at the same frequency, the imaging fails since the superposed individual contributions can no longer be separated from one another.

This problem may be solved as follows: the various frequencies to be used can be split, usually by a few tenths of a percent, frequently separated by powers of two. Thus, the n different excitation coils can be marked by splitting the excitation frequencies into n-tuple closely spaced frequencies (multiple-carrier concept). As far as the choice of frequency interval is concerned, this must be selected so that on the one hand it still allows the separation of individual excitation signals, e.g. by synchronous rectification (e.g. 1 kHz) and on the other hand, the conductivity of the target object can be assumed to be constant within the bandwidth of the resulting sub-carrier packets.

This process variant is shown in FIG. 10 for two frequencies in the β dispersion range of typical tissue. The principle of multi-sine multiple-carrier excitation is shown for the example of three excitation coils and two measurement frequencies f₁ and f₂. Both frequencies are split into closely adjacent but still separable sub-carriers fᵢⱼ (i is the index of the base frequency, j is the index of the sub-carrier). The individual coils are supplied with different sub-carriers so that the coil j is assigned to the superposition of all the frequencies with the sub-carrier index j. Their contributions are separated by suitable known methods on the receiving side, for example, by synchronous rectification or Fourier analysis.

1. An apparatus for magnetic induction tomography with at least one excitation coil (SP1, SP2, SP3) for the introduction of an alternating magnetic field into a target body to be investigated with inhomogeneous conductivity distribution at several excitation positions and at least one receiver coil (ES1, ES2, ES3) for the pickup of received signals at several different receiving positions with a means for the processing of the received signals which reconstructs an image of the spatial electrical properties in the object from the amplitudes and phases of the received signals, wherein the means for the processing of the received signals is capable of determining a correction factor (γ) by measuring at least two different frequencies (f₁, f₂) and introducing a perturbation (Vᵣₑ) of the coils and/or field geometry so that the spurious signals (artifacts) generated by changes of the geometry during the object measurement can be widely eliminated.

2. The apparatus according to claim 1 comprising a plurality of excitation coils (SP1, SP2, SP3) and a plurality of receiver coils (ES1, ES2, ES3) which are positioned stationary with respect to the object.

3. The apparatus according to claim 1 wherein the excitation and/or receiver coils (SSi) are movable at least in one degree of freedom so that a movement can be introduced in at least one of the coils.

4. The apparatus according to claim 3 wherein an actuator means (ANT) is provided for introducing a movement in at least one of the coils.

5. The apparatus according to claim 1 wherein a movable conductive perturbation object is provided in a region of the coils.

6. The apparatus according to claim 1 wherein the receiving coils (ES1, ES2, ES3) are built as gradiometer coils.

7. A method for magnetic induction tomography, with which an object with inhomogeneous passive electrical properties is exposed to alternating magnetic fields with coils located at different excitation positions, AC voltage signals which contain information about the electrical conductivity and its distribution in the object, are picked up with receiver coils located at different receiving positions and
an image of the spatial electrical properties in the object is reconstructed from the amplitudes and phases of the received signals, such that a measurement is carried out at at least two frequencies (f₁,f₂) and an additional perturbation (Vᵣₑ) of the coils and/or the field geometry so as to determine a correction factor (γ) with which it is possible to widely eliminate spurious signals (artifacts) generated by changes of the geometry during the object measurement.

8. The method according to claim 7 wherein the perturbation is introduced by an alternating movement of the coils relative to each other.

9. The method according to claim 7 wherein the perturbation is introduced by moving a sample in the sensitive region of the coils.

10. The method according to claim 7 wherein the perturbation is introduced by not previously defined, statistical movements of the coils.

11. The method according to claim 7 wherein the object is exposed to the alternating magnetic fields of several excitation coils which are stationary with respect to the object and that signals are received and processed from several receiver coils which are stationary with respect to the object.

12. The method according to claim 7 wherein the excitation frequencies (f₁,f₂) are split up into several closely spaced sub-frequencies (f₁₁, f₁₂, f₁₃; . . . f₂₁, f₂₂, f₂₃), whereas the closely neighboring sub-frequencies deviate from each other only insignificantly with respect to the frequency dependence of the passive electrical properties of the target tissue.

13. The method according to claim 12 wherein the neighboring subfrequencies deviate from each other by less than 10%.

14. The method according to claim 12 wherein the number of excitation coils corresponds to the number of sub-frequencies (f₁₁, f₁₂, f₁₃; . . . f₂₁, f₂₂, f₂₃) per excitation frequency (f₁, f₂) and each first (SP1), second (SP2) third (SP3) etc. excitation coil is fed with the first (f₁₁, f₂₁), second (f₁₂, f₂₂), third (f₁₃, f₂₃) etc. sub-frequency of the excitation frequency (f₁, f₂).
